(19) United States
(12) Patent Application Publication
(10) Pub. No.: US 2006/0063285 A1
(43) Pub. Date: Mar. 23, 2006

(54) Methods for measuring die temperature

(76) Inventor: Joseph P. Miller, Cypress, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/948,600

(22) Filed: Sep. 23, 2004

(51) Int. Cl. H01L 21/66

(52) U.S. Cl. 438/17

(57) ABSTRACT

Methods for measuring device temperature. In one example, device temperature may be determined by measuring a voltage across a diode arranged to provide electrostatic discharge protection for the die and calculating the die temperature using the voltage measured across the diode. Alternatively, other components on the die, not dedicated to temperature measurement may also be used to measure the die temperature.

### BACKGROUND

This section is intended to introduce the reader to various aspects of art, which may be related to various aspects of the present invention that are described or claimed below. This discussion is believed to be helpful in providing the reader with background information to facilitate a better understanding of the various aspects of the present invention. Accordingly, it should be understood that these statements are to be read in this light, and not as admissions of prior art.

Typically, computer system manufacturers design system components, such as very large scale integration (VLSI) devices, application specific integrated circuits (ASICs), processors and memory devices, to operate within a predetermined temperature range. If the temperature of the device exceeds the predetermined temperature range (i.e., the device becomes too hot), the device may not function properly (if at all), thereby potentially degrading the overall performance of the device and the computer system. Accordingly, it is often desirable for a computer system and its components to operate within a thermally benign environment.

Because of the temperature considerations involved in designing devices, it is often advantageous to measure the temperature of a chip or die during operation and under bias conditions. Generally, after a die is manufactured, the die is incorporated into a device and/or a system, and device temperature measurement is performed during system testing and validation, system design, or system manufacture. It may also be desirable to measure device temperature after the system has been manufactured and shipped. One technique for measuring device temperature is to attach a thermocouple to the device such that the temperature can be measured during operation of the device. Disadvantageously, thermocouples may be prohibitively large and cumbersome for measuring small devices. Further, as will be appreciated, the device generally includes a die, such as in integrated circuit chip, that is typically packaged in a protective encapsulant, such as a molded resin. By placing the thermocouple on the outside of the encapsulant, the thermocouple only measures the temperature of the packaging material, rather than the die itself. This may result in inaccuracies in device temperature measurement since it is generally the temperature of the die that determines whether a device will operate properly. Regardless of the drawbacks associated with the thermocouples, thermocouples provide the most commonly used mechanism for measuring device and die temperature.

A less widely used technique for measuring die temperature in devices, such as ASICs and VLSI devices, is to design the die such that it includes one or more devices on the die which may be used to specifically measure the die temperature. Disadvantageously, adding devices to a die occupies valuable real estate on the die. As will be appreciated, the ever-increasing demand for smaller system components may preclude the addition of devices on the die specifically configured for measuring die temperature. Another related factor is that if a device for measuring die temperature is fabricated directly on the die, input pins configured to provide access to the active components on the die from external sources, are generally coupled to the temperature devices and reserved specifically for temperature measurement. As with die real estate, the scarcity of the input pins on the die may be prohibitive in reserving one or more pins specifically for temperature measurements.

### BRIEF DESCRIPTION OF THE DRAWINGS

Advantages of one or more disclosed embodiments may become apparent upon reading the following detailed description and reference to the drawings in which:

FIG. 1 illustrates a partial schematic diagram of a die having an integrated electrostatic discharge (ESD) protection diode;

FIG. 2 is a partial schematic diagram of a die having an integrated electrostatic discharge (ESD) protection diode configured to facilitate die temperature measurement in accordance with embodiments of the present techniques; and

FIG. 3 is a flow chart illustrating methods for measuring the temperature of a die using the electrostatic discharge (ESD) protection diodes in accordance with embodiments of the present techniques.

### DETAILED DESCRIPTION OF SPECIFIC EMBODIMENTS

One or more exemplary embodiments of the present invention will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

In accordance with exemplary embodiments of the present invention, there are provided methods for accurately measuring die temperature without using thermocouples and without adding temperature measuring devices to the die. Specifically, in accordance with embodiments of the present invention, integrated electrostatic discharge (ESD) protection diodes which are typically coupled to the input pins of devices such as VLSI devices, ASICs, memory devices and processors, for instance, are implemented to calculate the temperature of the die. Advantageously, these techniques may be implemented on any device having integrated ESD diodes coupled to the input pins of the device without requiring the addition of specific components directed to temperature measurement on the die. The temperature measurements can be made during operation of the device and under operational biasing conditions. As used herein, “adapted to,” “configured to,” and the like refer to elements that are sized, arranged or manufactured to form a specified structure, to perform a specified function or to achieve a specified result.

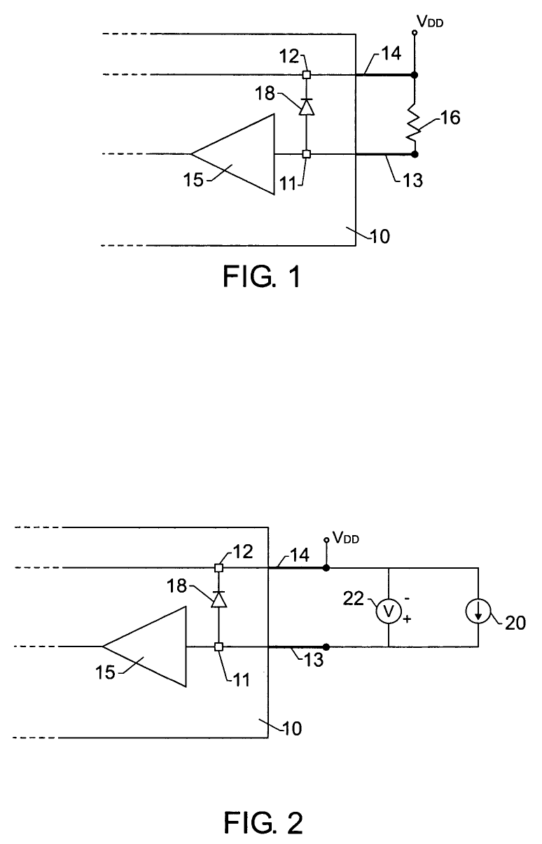

Referring initially to FIG. 1, a die 10 is illustrated. The die 10 may be implemented in a device such as a VLSI device or ASIC device, for instance. The die 10 generally includes a large number of integrated circuits having a number of field effect devices (not shown). The die 10 includes internal pads 11 and 12 which are coupled to various integrated circuits on the die 10. The pads 11 and 12 may be electrically coupled to respective input pins 13 and 14 to provide external connections for routing signals to and from the die 10. As will be appreciated, the input pins 13 and 14 may be provided by the package incorporating the die 10 therein. The input pin 14 may be coupled to a voltage supply having a high voltage level V_{DD}. The input pin 14 provides a voltage path to active integrated circuits on the die 10 through the pad 12. The input pin 13 is coupled to an input buffer 15 through the pad 11. As will be appreciated, the input pin 13 provides an input signal path to the active integrated circuits on the die 10 through the input buffer 15. As will be appreciated, the input pin 13 of the die 10 may be implemented for setting modes in the die 10 and may be pulled to a high voltage level V_{DD}. The input pin 13 is generally pulled high through a pull-up resistor 16, such that the input pin 13 remains electrostatically high during operation of the device. The pull-up resistor 16 is generally located off-chip (i.e., external to the die 10), as will be appreciated by those skilled in the art.

Integrated circuits employing field effect devices have demonstrated a general susceptibility to electrostatic discharge (ESD). With the miniaturization of circuit features, ESD may affect the die 10 more and static electricity generated by daily activity alone may destroy or substantially harm the die 10 and the device in which is has been incorporated. Accordingly, most dies employ integrated protection circuits such as the ESD protection diode 18. The ESD protection diode 18 is fabricated on the die 10 (or “integrated”) and is coupled between the pads 11 and 12. As previously described, the input buffer 15 is coupled to the input pin 13 and the voltage supply V_{DD} such that any electrostatic discharge may be dissipated through the ESD protection diode 18 such that the die 10 is protected from excessive static voltage build up. As will be appreciated, while only one integrated ESD protection diode 18 is illustrated, the die 10 may include ESD protection diodes 18 on any or all of the input pins of the device.

FIG. 2 illustrates a circuit set-up for electrical measurements associated with the diode 18 in carrying out temperature measurements in accordance with embodiments of the present invention. Specifically, FIG. 2 illustrates a technique for utilizing the ESD protection diode 18 to calculate the temperature of the die 10 during operation of the device. Because the ESD protection diode 18 is integrated in the die 10, temperature measurements made using the ESD protection diode 18 will more accurately reflect the temperature of the die 10 during operation, rather than the temperature of the device or package in which the die 10 is incorporated. While only one integrated ESD protection diode 18 is illustrated, it should be understood that the present techniques may be implemented with any integrated ESD protection diodes 18 which may be coupled to the input pins of the device. In accordance with one exemplary embodiment, the pull-up resistor 16 of FIG. 1 is replaced with a current source 20 and a voltage meter 22. The current source 20 is arranged to generate a forward current through the ESD protection diode 18. The voltage meter 22 is arranged to measure the voltage across the ESD protection diode 18 while the ESD protection diode 18 is being driven by the current source 20. As described further below, in accordance with the present embodiments, the temperature of the die 10 may be measured during circuit operation of the die 10 and application of the supply voltage VDD.

During temperature measurement, the current source 20 may be operated to forward bias the ESD protection diode 18 with a weak current, such as a current less than 1 μA. As will be appreciated, using the current source 20 to provide a weak current will allow the die 10 to function at a high logic level without stressing the diode 18 or the input pin 13. In one exemplary embodiment, the current source 20 may comprise a resistor and a battery. However, any suitable device capable of generating currents less than approximately 10 mA may be used.

The voltage meter 22 may be used to measure voltage across the ESD protection diode 18 while current is being driven through the ESD protection diode 18 such that an accurate die temperature may be calculated. In accordance with one exemplary embodiment, the voltage meter 22 may be used to measure successive currents produced by the current source 20. For instance, at a first time, a first current, such as 100 μA (I_{HIGH}) may be used to forward bias the ESD protection diode 18, and a first voltage measurement (V1) may be made using the voltage meter 22. At a second time, a second current such as 10 [2A (I_{LOW}) may be generated by the current source 20, and a second voltage (V2) may be measured across the ESD protection diode 18 using the voltage meter 22. As will be appreciated, the temperature (T) of the device may be calculated using two currents and two voltage measurements taken at those currents. In accordance with the present exemplary embodiment, any two currents will be sufficient to calculate the temperature. However, as will be appreciated by those skilled in the art, the currents should be sufficiently different from one another to produce an accurate temperature calculation. For instance, in one exemplary embodiment, the currents have a ratio of at least 10:1 with respect to one another. The temperature (T) of the die 10 may be calculated in accordance with the following equation:

$$T = \frac{( V2 - V1 )}{86.4 * ln [ {I}_{HIGH} / {I}_{LOW} ]}$$

Advantageously, by using an integrated device which is already present on the die 10, such as the integrated ESD protection diode 18, the current source 20 and the voltage meter 22 may be used to obtain an accurate temperature of the die 10 while the device is in operation. The exemplary embodiments provide a mechanism for obtaining accurate die temperature measurements, without implementing thermocouples and without adding specific elements to the die 10 or the device in which the die 10 has been incorporated, which are dedicated to temperature measurement. As used herein, “dedicated to temperature measurement” refers to being used solely for the purpose of measuring temperature of the die 10.

As will be appreciated, other devices configured to drive current through a diode and calculate temperature based on the current through the diode may also be utilized in accordance with embodiments of the present invention. Further, any alternate techniques used for measuring the temperature of the die 10 by utilizing device components already present on the die 10, such as, but not limited to the integrated ESD protection diode 18, may be implemented to calculate accurate temperature measurements of the die 10 without implementing thermocouples or other cumbersome external measurement devices and without necessitating the addition of components fabricated on the die 10 or the device in which it is incorporated.

In accordance with further exemplary embodiments, the die 10 may be optimized during manufacture to provide more accurate temperature testing. With knowledge during manufacture that the ESD protection diode 18 may be used for temperature testing, the ESD protection diode 18, which previously had the sole purpose of ESD protection, may be calibrated to provide more accurate results when used for temperature testing. Some or all of the integrated ESD protection diodes 18 that may be coupled to the input pins of the die 10 may be calibrated more accurately to increase the accuracy of the die temperature measurements. Further, the distribution of the ESD protection diodes 18 may be taken into account to characterize temperature variations across the die 10 during temperature testing. Advantageously, and in accordance with the present exemplary embodiments, design and layout of the die 10 remains otherwise unaltered by the further calibration of one or more of the ESD protection diodes 18 to provide more accurate temperature measurements.

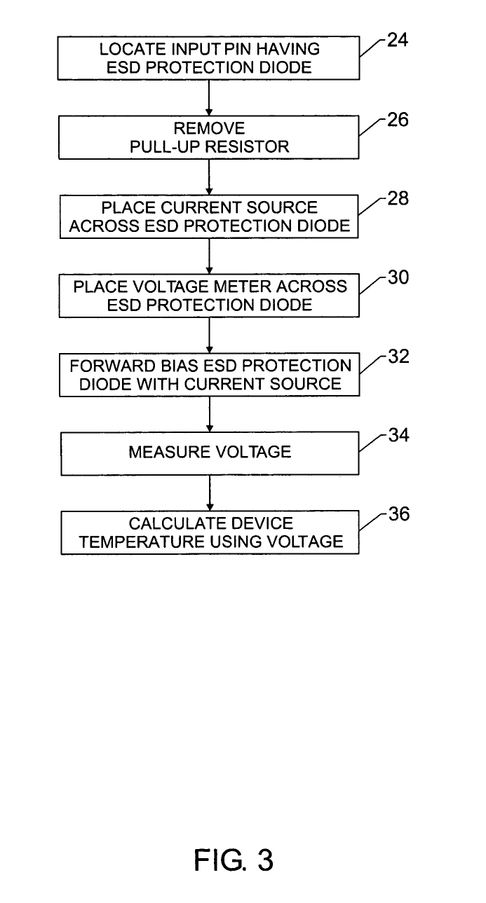

Referring now to FIG. 3, a flow chart illustrating an exemplary process for measuring the temperature of the die 10 in accordance with exemplary embodiments of the present inventions is illustrated. First, a die (such as the die 10 ) having an input pin (such as the input pin 13) and having an integrated ESD protection diode (such as the ESD protection diode 18) is located, as indicated in block 24. At an external system level, the conventional pull-up resistor 16 which is generally coupled across the ESD protection diode 18, is removed, as indicated in block 26. The pull-up resistor 16 may be replaced with a current source 20 and a voltage meter 30, as indicated in blocks 28 and 30. Alternately, the pull-up resistor 16 may be replaced with a device which is configured to generate a current through a diode and to measure the temperature across the diode.

During temperature testing, the current source 20 is used to forward bias the ESD protection diode 18, as indicated in block 32 and a voltage is measured across the ESD protection diode 18 using the voltage meter 22, as indicated in block 34. As previously described, in accordance with one exemplary embodiment of the present invention, multiple voltage measurements may be taken at various currents. Finally, the temperature of the die 10 may be calculated using the voltage measurements taken by the voltage meter 22. Alternately, rather than using a current source 20 and a voltage meter 22, a temperature measuring device configured to generate current and to directly calculate the temperature across a diode may be used.

While the invention may be susceptible to various modifications and alternative forms, specific embodiments have been shown by way of example in the drawings and will be described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of measuring temperature of a die comprising:
measuring a voltage across a diode integrated on the die and coupled to an input pin of the die, wherein the diode is arranged to provide electrostatic discharge protection for the die; and
calculating a die temperature using the voltage measured across the diode.

2. The method, as set forth in claim 1, wherein measuring the voltage comprises:
measuring a first voltage across the diode driven by a first current; and
measuring a second voltage across the diode driven by a second current.

3. The method, as set forth in claim 2, wherein calculating the die temperature comprises calculating the die temperature using each of the first voltage, the first current, the second voltage and the second current.

4. The method, as set forth in claim 1, wherein calculating the device temperature comprises automatically calculating the device temperature after measuring the voltage across the diode.

5. A method of measuring temperature of a die comprising:
coupling a current source across a diode integrated on the die and coupled to an input pin of the die, wherein the diode is arranged to provide electrostatic discharge protection for the device;
coupling a voltage meter across the diode; and
generating current through the diode using the current source;
measuring voltage across the diode using the voltage meter while the die is operational; and
calculating a die temperature using the voltage measured.

6. The method, as set forth in claim 5, wherein generating current and measuring voltage comprise:
forward biasing the diode with a first current using the current source;
measuring a first voltage across the diode using the voltage meter while the diode receives the first current;
forward biasing the diode with a second current using the current source; and
measuring a second voltage across the diode using the voltage meter while the diode receives the second current.

7. The method, as set forth in claim 6, wherein calculating the die temperature comprises calculating the temperature of the die using the first voltage and the second voltage.

8. A method of measuring temperature of a die comprising:
forward biasing an electrostatic discharge protection diode integrated on the die;
measuring a voltage across the diode; and
calculating a temperature of the die using the measured voltage.

9. The method, as set forth in claim 8, wherein measuring the voltage comprises measuring the voltage while the die is operating.

10. The method, as set forth in claim 8, wherein measuring the voltage comprises:
measuring a first voltage across the diode driven by a first current; and
measuring a second voltage across the diode driven by a second current.

11. The method, as set forth in claim 8, wherein calculating the die temperature comprises automatically calculating the die temperature after measuring the voltage across the diode.

12. A method of measuring a temperature of a die, comprising:
measuring one or more current or voltage values correlating to an integrated component on the die, wherein the integrated component is not dedicated to use in measuring the temperature of the die; and
calculating a temperature of the die using the one or more current or voltage values.

13. The method, as set forth in claim 12, wherein measuring one or more current or voltage values comprises measuring one or more voltages across a diode.

14. The method, as set forth in claim 12, wherein measuring one or more current or voltage values comprises measuring one or more current or voltage values correlating to a diode, wherein the diode is configured to protect the die againstelectrostatic discharge.

15. The method, as set forth in claim 12, wherein the acts are performed while the die is operational.
